(19) United States
(12) Patent Application Publication
(10) Pub. No.: US 2024/0002674 A1
(43) Pub. Date: Jan. 4, 2024

(54) COMPOSITION AND METHOD FOR IMPROVING DURABILITY OF ELECTRICALLY INSULATING AND WATERPROOFING GEL COATING SYSTEMS

(71) Applicant: ACTNANO, INC., Cambridge, MA (US)

(72) Inventors: Justin KLEINGARTNER, Boston, MA (US); Sruti BALASUBRAMANIAN, Quincy, MA (US); Liam DOYLE, Somerville, MA (US); Cedric VIRY, Cambridge, MA (US); Julia ZHAO, Medford, MA (US)

(73) Assignee: ACTNANO, INC., Cambridge, MA (US)

(21) Appl. No.: 18/255,771

(22) PCT Filed: Dec. 3, 2021
(86) PCT No.: PCT/US2021/061909

§ 371 Date: Jun. 2, 2023

Related U.S. Application Data
(60) Provisional application No. 63/240,533, filed on Sep. 3, 2021.
(60) Provisional application No. 63/121,747, filed on Dec. 4, 2020.

(51) Int. Cl. C09D 5/08; C09D 5/02; C09D 153/00; C09D 123/22; C09D 183/04; C09D 133/12; C09D 7/48; C09D 7/45; C09D 7/47; C09D 7/41; C09D 7/63; C09D 7/61; C09D 7/65; H05K 3/28

(52) U.S. Cl. CPC C09D 5/08; C09D 5/025; C09D 153/00; C09D 123/22; C09D 183/04; C09D 133/12; C09D 7/48; C09D 7/45; C09D 7/47; C09D 7/41; C09D 7/63; C09D 7/61; C09D 7/65; H05K 3/285; H05K 1/18

(57) ABSTRACT

There is disclosed a composition for forming a conformal gel coating to protect a substrate from various environments, wherein the composition comprises at least one film former, at least one additive and optionally at least one solvent. The composition is deformable, flowable, electrically insulating, and does not contain fluorine when applied as a coating. Gel coatings, methods of applying such coating to substrates, as well as the coated substrates are also disclosed. Non-limiting examples of such substrates include a printed circuit board, an assembled electronic device or an automotive part.

### CROSS REFERENCE TO RELATED APPLICATION

This application claims the benefit of priority to U.S. Provisional Application Nos. 63/121,747, filed Dec. 4, 2020 and 63/240,533 filed Sep. 3, 2021, both of which are incorporated herein by reference in their entireties.

### TECHNICAL FIELD

The present disclosure generally relates to gel-state coatings that form a protective coating on a substrate, and methods of making the same. The present disclosure also relates to compositions used to make such coatings, as well as methods of applying such coatings to desired substrates, which may include electronic devices, such as a printed circuit board.

### BACKGROUND

Electronic devices are comprised of electrically conductive and insulating components, which can be adversely affected by exposure to harsh environments. Exposure to liquids like water will often lead to corrosion of these components or a short circuit that will eventually destroy the function of the electronic device. In addition, as such devices become more sophisticated with increased functionality, they are being used in more hazardous environments, such as humidity, corrosive gasses, and aerosolized or bulk liquids, that can degrade the functionality of the device.

Electronic devices fail when exposed to these environments since conductive media can provide a pathway for current flow from components that are under bias. Most of these failures manifest as corrosion of electronic components or as failure of performance of the components. In addition to the components themselves failing, the conformal coatings can also fail these strenuous conditions due to chemical degradation which may eventually lead to loss of insulation properties.

As a result, durable electrically-insulating, coatings are becoming a more popular form of protection of such devices. Traditional coatings require masking of certain parts to ensure there is no inhibition of the flow of electric current through connectors, test points, or grounding contacts. This process is expensive and time consuming, which adversely affects the overall electronics manufacturing process.

Traditional conformal coatings aim to improve on their durability by increasing their mechanical strength. Furthermore, traditional conformal coating chemistries using rely on forming heavily crosslinked networks that cannot be deformed easily. This results in a hard and rigid coating that requires compromises during the electronics manufacturing process (e.g., masking or selective coating of certain components).

Accordingly, there is a need for a coating that exhibits improved functional durability, allowing it to perform its function over the lifetime of the device, while also retaining the ability to deform and flow. Because of the improvement in functional durability, the disclosed coating can be used in a variety of applications when applied to various devices or substrates, such as in the automotive, household and industrial appliances, consumer electronics, aerospace, military, and chemical industries to protect the device or substrate from a variety of environments. Non-limiting examples of potential uses include coatings and methods that allow for protection of electronic devices from harsh environments and contaminates, such as particulates including dust and dirt, as well as liquids, including water and bodily fluids. Furthermore, there is a need for a coating that can be applied without the need to mask components, such as on a printed circuit board, prior to coating. There is also a need for a durable, deformable, and flowable coating that can cover an entire printed circuit board, without inhibiting the functionality of the device.

### SUMMARY

In view of the foregoing, there is disclosed a composition that is used to form a durable gel-state coating to protect a device or substrate, methods of making such a coating and methods of using such a coating, as well as devices and substrates protected with such a coating.

In one embodiment, there is disclosed a composition for forming a conformal gel coating to protect a substrate from various environments, the composition comprising: at least one film former; and at least one additive and optionally at least one solvent, wherein the composition is deformable, flowable, electrically insulating, and does not contain fluorine when applied as a coating.

There is also disclosed a conformal gel coating to protect an electronic element from various environments, the coating comprising: at least film former; and at least one additive and optionally at least one solvent, wherein the gel coating is deformable, flowable, electrically insulating, and does not contain fluorine.

In another embodiment, there is disclosed a method of treating an electronic device with a gel conformal coating, the method comprising: applying the gel conformal coating to the electronic device, the gel conformal coating comprising a film former, and an additive, the coating composition optionally further comprising at least one solvent, dye, pigment or combinations thereof.

In yet another embodiment, there are disclosed various devices or substrates on which the coating is applied. These devices or substrates may include an automotive part or a printed circuit board, with a gel-state coating described herein. The gel-state coating described herein is made from a composition comprising: at least one film former, and at least one additive that improves at least one of the mentioned performance properties of the coating.

### BRIEF DESCRIPTION OF THE DRAWINGS

The accompanying figures, which are incorporated in and constitute a part of this specification, illustrate several embodiments of the invention and together with the description, serve to explain the principles of the invention.

FIG. 1 is a flow chart showing a representative antioxidant (AO) additive action mechanism according to a disclosed embodiment.

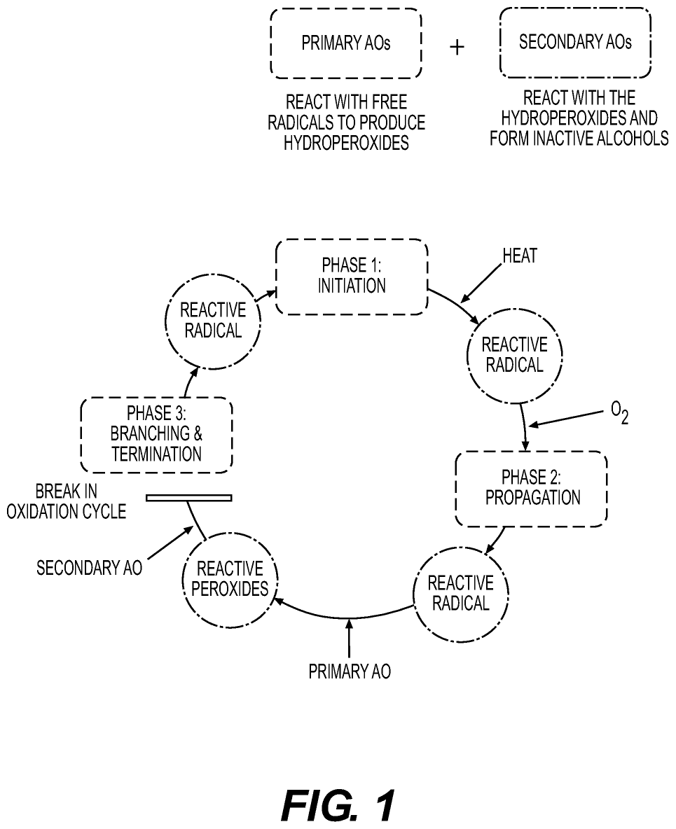

FIG. 2 is a schematic showing surface insulation resistance measurement set-up.

FIG. 3 shows a schematic demonstrating migration of additive from coating to the coating/substrate interface to prevent degradation of the coating or substrate.

FIG. 4 shows a schematic demonstrating migration of additive from coating to coating/air interface to prevent degradation of the coating or substrate.

FIG. 5 shows a schematic demonstrating stepwise application of various additives.

FIG. 6 shows a schematic demonstrating the migration of additives to target specific components from external environments that may affect coating performance.

FIG. 7 shows a schematic demonstrating migration of additive from coating to coating/air interface to change mechanical or diffusion properties at the interface.

### DETAILED DESCRIPTION

As used herein, “conformal coating” refers to a film that follows the contours of the substrate on which it is applied, such as a printed circuit board or its components, in a continuous fashion without breaks or openings. The conformal coating described herein protects the substrate, such as electronic circuitry, against the environment and liquids or particulates, including water, sweat, or other moisture, dirt and dust, as well as chemicals.

As used herein, “film former” refers to a material capable of forming a cohesive, continuous film upon application to a solid surface. The film formers described herein are typically used in the form of organic or aqueous solutions or dispersions, comprising organic or aqueous solvents that allow the film-forming materials to form films upon evaporation of the solvent.

As used herein, “gel” or “gel-state” refers to a material or a composite of materials that form internal networks either due to chemical crosslinking and/or physical association between constituent components. A gel coating exhibits non-Newtonian, viscoelastic, viscoplastic, and/or elastoviscoplastic flow properties.

As used herein, “deform” or “deformability” refers to the ability of the gel to strain (e.g., stretch, bend, etc.) under compressive, tensile, or shear stresses typically incurred during the assembly of electronics or under temperature ranges typically seen during processing of electronics.

As used herein, “flow” or “flowability” refers to the ability of the gel to behave like a fluid, which undergoes a steady rate of shearing deformation under the application of a shear stress.

As used herein, a “non-Newtonian fluid,” or versions thereof, means a fluid that does not follow Newton's Law of Viscosity (e.g., a fluid whose viscosity is variable based on applied stress or force). The resulting coating exhibits non-Newtonian behavior that is described by the coating's non-linear relationship between shear stress and shear rate or the presence of a yield stress. A non-Newtonian fluid comprises a single or multi-phase fluid that exhibits non-Newtonian behavior. It may also include single or multiple constituents. The non-Newtonian fluid is sometimes referred to as a complex fluid. In one embodiment, the non-Newtonian fluid is viscoelastic.

As used herein, “viscoelastic” means a material that exhibits both viscous and elastic characteristics when undergoing deformation (i.e., the material both stores energy and dissipates energy during a periodic/cyclic oscillatory shearing deformation). This is commonly reported in terms of non-zero measurable values of both a storage modulus G′ and a loss modulus G″.

As used herein, “viscoplastic” refers to an inelastic behavior of a material in which a material undergoes unrecoverable deformations when a critical load level (known as the yield stress) is reached. The main difference between a viscoplastic and viscoelastic material is the presence of a yield stress. A viscoplastic material has a yield stress below which it will not flow, whereas a viscoelastic material will deform and flow under the application of any finite shear stress.

As used herein, “elastoviscoplastic” refers to a broad class of materials such as the gel coatings described in this patent which show elastic, viscous and plastic response characteristics under different levels of applied shear stress or strain. Below a critical stress, often referred to as a yield stress, the material does not undergo steady flow but undergoes a transient deformation in which some strain is accumulated elastically and some energy is dissipated by plastic (irreversible) deformation. When the critical load level is reached (i.e., the yield stress is exceeded) the material begins to flow like a liquid but still exhibits viscoelastic properties (i.e., it has measurable values of the elastic models G′ and loss modulus G″) because some of the initial deformation is stored elastically and some of the external work applied to the material is dissipated viscously. When the applied load is removed this elastoviscoplastic response can be distinguished in a rheometer by a partial (i.e., elastic) recoil or unloading but some irreversible deformation is accumulated due to the plastic nature of the material.

As used herein, “durability”, refers to the ability of the coating material to maintain its functional properties (e.g., electrical insulation, hydrophobicity, appearance, morphology, and physical and chemical properties, etc.) even after exposure to various environmental stresses. The changes in the performance of the coating could be caused by a variety of stresses including but not limited to: continued exposure to heat, repeated and intermittent exposure to extreme temperatures, low temperature exposure, high temperature and/or humidity exposure, salt fog exposure, noxious or corrosive gas exposure, UV exposure, and other chemical exposure. These stresses can cause damage to the coating material, including but not limited to cracking, oxidation, chain scission, radical crosslinking, phase separation, phase change, coating flow, browning, delamination, blistering, and the like.

The industry standard tests for evaluating the durability of the conformal coatings to meet life-cycle requirements are set by suppliers of the electronic components, the companies that assemble the electronic components or PCBs into consumer or automotive devices, or third-party organizations that govern how conformal coatings should be evaluated. Some of these industry standard tests include Ford Motor Company's Corporate Engineering Test Procedure, Volkswagen VW 80000 Electric and Electronic Components in Motor Vehicles Test Procedure, BMW Group Standard 95011-5 Qualification of Conformal Coatings in Motor Vehicles, IPC-CC-830C, and MIL-STD-810G.

As used herein, a “solvated coating” refers to the coating which contains a solvent to help it spread when applied to a substrate, e.g., to a composition that still includes a solvent. If “solvated” or any version thereof is not used in combination with “coating” then the coating is considered to be a dried coating on the substrate or device, e.g., without a solvent.

As used herein, “electrical insulation” refers to the property of a material to provide a resistance to electrical flow. For example, in one non-limiting embodiment, when the gel-state coating is applied on an active component which is under bias, the coating provides an electrical resistance greater than 10³ ohm or a dielectric breakdown voltage greater than 1.5 kV/mil.

In one embodiment, a gel-state coating comprises a composition that exhibits both viscous and elastic characteristics. A viscoelastic material, unlike a purely elastic material, will flow like a viscous liquid under load but will maintain the elastic characteristics of a solid when not under load. Viscoelasticity has been well-studied and the behavior of viscoelastic materials is known in the arts.

In another embodiment, a gel-state coating comprises a composition that exhibits elastoviscoplastic characteristics. A elastoviscoplastic material, unlike a viscoelastic material, has a critical load level (i.e., yield stress) below which it will not flow. Elastoviscoplasticity has been well-studied and the behavior of elastoviscoplastic materials is known in the arts. The elastic and plastic properties associated with the disclosed compounds allow the material to resist liquid contamination and material deformation due to body forces (e.g., gravity), and the viscous properties allow the material to redistribute itself under stress and over time, such as to be displaced when a force is applied or to evenly cover a surface.

The properties of a gel-state coating therefore make it favorable for use as a coating on electronic devices. Desirable film formers comprise materials that adhere or adsorb to the surface of the electronic device to maintain a thin film, typically in the range of nanometers to hundreds of microns. Thicker films can be attained when the fluid exhibits a yield stress.

The use of a gel-state coating may achieve benefits that do not exist with the use of traditional conformal or vacuum coatings. The viscous or plastic nature of a film former may eliminate the need to mask certain components prior to coating an electronic device. Typically, masking certain components (e.g., connectors and grounding traces) is used to allow for the flow of an electric current through the masked areas in the coating. A gel-state coating instead exhibits viscoplastic properties by flowing or deforming when a component is introduced to the electronic device. Flow or deformation of the gel coating allows the component to connect to the electronic device with no interference. The gel-state coating will exhibit non-Newtonian, viscoelastic, viscoplastic or elastoviscoplastic properties. Masking a component is not necessary as the electric current will pass to the component, however, masking may still be done if desired.

In alternative embodiments, the film former that enables the various mechanical properties of the coating could consist of polyamides, polynitriles, polyacrylamides, polycarbonates, polysulfones, polyterephthalates, polysulfides, or combinations thereof. The film formers may have unique polymer topologies including linear polymers, cyclic polymers, branched polymers, hyperbranched polymers, graft polymers, star polymers, bottlebrush polymers, gels with various branch functionality, or combinations thereof. Alternative embodiments can be made from homopolymers, copolymerization of two or more monomers, polymer blends, interpenetrating polymer networks of one or multiple polymer or copolymer types. Copolymers can be block, statistical, random, or alternating copolymers. Furthermore, alternative embodiments of the film former could be made from loosely crosslinked polymer networks (i.e., where the gel nature or the elastoviscoplastic flow property is maintained) that contain covalent bonds, dynamic bonds (hydrogen bonding, metal-organic coordination, pi-pi stacking, etc.), polymer entanglement, or a combination of these types. All types of crosslinking can occur before the composition is applied on the substrate or after.

In an embodiment, there is described a composition for forming a coating having increased performance at extreme conditions, such as high and low temperatures, under UV light exposure, high humidity environment, corrosive salty environment, environments with noxious or corrosive gas mixtures, and sustained performance for long life cycle products like automotives.

For example, in one embodiment, a traditional coating system that is known to degrade when exposed to catalytically active metals, may be enhanced by adding a metal passivator and an antioxidant. The passivator and antioxidant concentrations are chosen based on the rate of decomposition of the gel coating and the exposed area of the catalytically active metal. The passivator and antioxidant are also chosen for their relative affinity to the catalytically active metal and their solubility in the gel coating. Additionally, the passivator and antioxidant can be chosen such that they preferentially migrate from the bulk of the coating to an interface. The catalytically active metal initiates the decomposition of the coating by generating free radicals. The passivator screens the catalytically active metal from other components of the coating. Primary and secondary antioxidants neutralize the free radicals. Additional additives like acid scavengers could be added to suppress the production of unfavorable by-products of free radical neutralization by the primary and secondary antioxidants.

Previous electrically insulating gel coatings did not contain stabilizers to increase durability of the formulation. Thus, the present disclosure solves the problems and deficiencies of prior compositions. In one embodiment, there is disclosed applying passivating components to metal substrates in a first layer before applying the gel coating in a second layer. In another embodiment there is disclosed a method of applying a gel coating to the board in a first layer followed by the application of an antioxidant rich layer. Combinations of these embodiments could also be used.

Deciding the nature of additives, quantities of additives, the method of formulation of the additives into a gel coating system through various unit operations are non-limiting ways in which the current disclosure differs from the previous processes.

The nature of additives formulated into the coating has a direct impact on the durability of the coating. Proprietary additive combinations are necessary to both prevent the coating itself from chemical and mechanical degradation as well as to protect the underlying substrate. For example, a metal substrate that the coating is in contact with could catalyze the degradation of the coating which thereby results in poor electrical insulation performance. In this case, a proprietary combination of a metal passivator that screens the metal/coating interface to protect the metal and primary and secondary antioxidants to protect the coating are necessary.

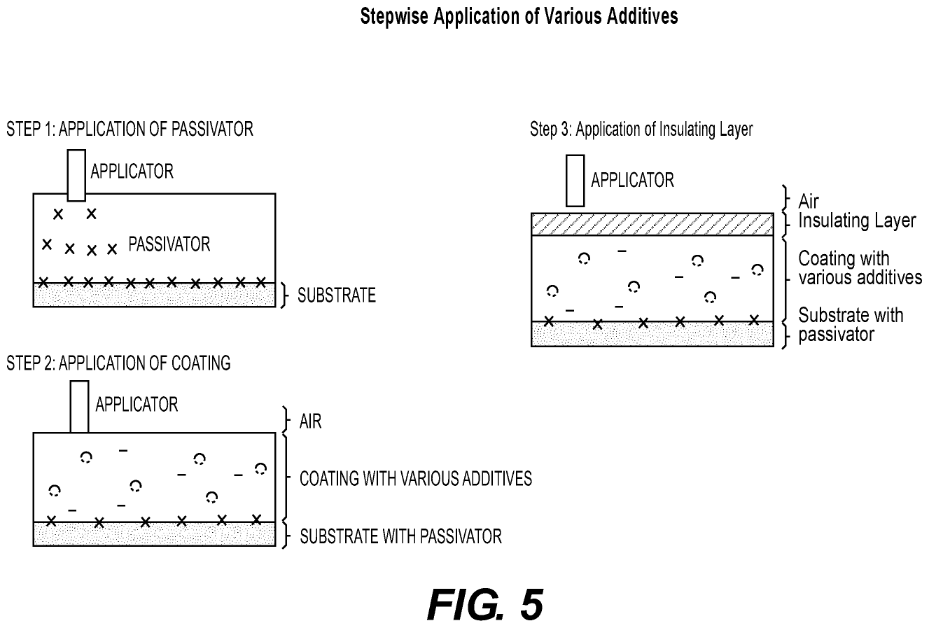

Proprietary additives formulations could address various failure mechanism of both the coating and active substrate based on the environment that the electronic component is exposed to. As shown in FIG. 5, a passivator formulated into the coating could migrate to the metal/coating interface to inhibit the catalytic degradation of other components in the coating. This invention pertains to choosing the appropriate additives such that they are able to migrate from the bulk phase to an interface in order to augment the interface such that the coating maintains its integrity. A primary antioxidant formulated into the coating could quench any free radicals that are formed either due to exposure to an active metal or from exposure to the environment. A secondary antioxidant formulated into the coating would further deactivate any byproducts of a primary antioxidant reacting with free radicals. This invention pertains to identifying the appropriate proprietary mixture of additives based on the electronic device and the environment it functions in while maintaining the deformability of the coating.

Similar to engineering the proprietary additives based on the environmental performance requirements, methods for engineering the deformability of the coating are also addressed in this application. For example, in order to connect through the coating, the coating has to be engineered to be ductile enough in the normal, tensile, and compressive directions and exhibit elastoviscoplastic flow properties. The coating could be engineered to demonstrate pencil hardness below 6B. The storage and loss moduli of the coating in the shear and tensile directions could be less than 10⁶ Pa at 25° C. when measured at frequencies between 1-100 rad/s. The coating could yield when deformed with a yield stress lower than 10⁴ Pa under shear and tensile directions at 25° C. between 1-100 rad/s.

In one embodiment, there are disclosed custom additive formulations that improve the performance of an existing coating. For example, if a gel coating degrades at higher temperatures, the current disclosure pertains to either changes in composition or processes to incorporate additives that will increase the durability of the coating by allowing it to resist degradation. Higher temperature could lead to oxidative degradation of the coating, which would change its chemical structure and prevent it from performing its function. In this situation, an antioxidant additive would inhibit the oxidation of the coating, making it more durable in that condition.

The additive mixture described herein may be chosen based on the deficiencies that are identified in the coating's performance. The additive mixture is then formulated to address these deficiencies. For example, if copper is identified as a catalyst that initiates free radical decomposition of a gel coating, the additive mixture would consist of a passivator that would migrate to the coating/copper interface to inhibit catalysis and an antioxidant to suppress any free radicals generated.

The addition of these additives would also result in preserving the gel nature of the coating which would prevent issues like flowing, liquefying, cracking, chipping, and other modes of macro-scale removal of the coating when exposed to extreme environments.

In one embodiment, the additive comprises at least one corrosion inhibitor, such as a carboxylic acid. One non-limiting example of a carboxylic acid that can be used in the present disclosure is Irgacor 843™, sold by BASF.

In one embodiment, the additive comprises at least one passivator, such as a hydrazide, triazole, or mixture thereof. Non-limiting embodiments of a hydrazide which can be used in the present disclosure include dodecanedioic acid, 1,12-bis[2-(2-hydroxybenzoyl) hydrazide] (CAS number 63245-38-5) or benzenepropanoic acid, 3,5-bis(1,1-dimethylethyl)-4-hydroxy-, 2-[3-[3,5-bis(1,1-dimethylethyl)-4-hydroxyphenyl]-1-oxopropyl]hydrazide (CAS number 32687-78-8).

Non-limiting embodiments of a triazole which can be used in the present disclosure include benzamide, 2-hydroxy-N-1H-1,2,4-triazol-3-yl- (CAS number 36411-52-6), 1H-benzotriazole-1-methanamine, N,N-bis(2-ethylhexyl)-ar-methyl-(CAS number 94270-86-7) or 1H-1,2,4-triazole-1-methanamine, N,N-bis(2-ethylhexyl)- (CAS number 91273-04-0).

In one embodiment, the additive comprises at least one primary antioxidant, such as an amine or phenolic. Non-limiting embodiments of an amine primary antioxidant which can be used in the present disclosure include Benzenamine, N-phenyl-, reaction products with 2,4,4-trimethylpentene (CAS number 68411-46-1), an alkylated amine, 1-naphthalenamine, N-phenyl-ar-(1,1,3,3-tetramethylbutyl) (CAS number 68259-36-9) or 4,4′-dioctyldiphenylamine (CAS number 101-67-7).

Non-limiting embodiments of a phenolic primary antioxidant which can be used in the present disclosure include benzenepropanoic acid, 3,5-bis(1,1-dimethylethyl)-4-hydroxy-, octadecyl ester (CAS number 2082-79-3), benzenepropanoic acid, 3,5-bis(1,1-dimethylethyl)-4-hydroxy-, 2,2-bis[[3-[3,5-bis(1,1-dimethylethyl)-4-hydroxyphenyl]-1-oxopropoxy]methyl]-1,3-propanediyl ester (CAS number 6683-19-8), a reaction mass of isomers of: C7-C9 alkyl 3-(3,5-di-tert-butyl-4-hydroxyphenyl) propionate (CAS number 125643-61-0), 1,3,5-triazine-2,4,6(1H,3H,5H)-trione, 1,3,5-tris {[3,5-bis(1,1-dimethylethyl)-4-hydroxyphenyl]methyl}- (CAS number 27676-62-6), or benzenepropanoic acid, 3-(1,1-dimethylethyl)-4-hydroxy-5-methyl-, 2,4,8,10-tetraoxaspiro [5.5]undecane-3,9-diylbis(2,2-dimethyl-2,1-ethanediyl) ester (CAS number 90498-90-1).

In one embodiment, the additive comprises at least one secondary antioxidant, such as a phosphite or thioether. Non-limiting embodiments of a phosphite secondary antioxidant which can be used in the present disclosure include tris(2,4-di-tert-butylphenyl) phosphite (CAS number 31570-04-4), butylidenebis[2-tert-butyl-5-methyl-p-phenylene]-P,P,P′,P′-tetratridecylbis(phosphine) (CAS number 13003-12-8), and 12H-dibenzo[d,g][1,3,2]dioxaphosphocin, 2,4,8,10-tetrakis(1,1-dimethylethyl)-6-[(2-ethylhexyl)oxy]- (CAS number 126050-54-2).

Non-limiting embodiments of a thioether secondary antioxidant which can be used in the present disclosure include propanoic acid, 3-(dodecylthio)-, 1,1′-[2,2-bis[[3-(dodecylthio)-1-oxopropoxy]methyl]-1,3-propanediyl] ester (CAS number 29598-76-3) and propanoic acid, 3,3′-thiobis-, 1,1′-ditridecyl ester (CAS number 10595-72-9).

In one embodiment, the composition disclosed herein includes a tackifier. Non-limiting examples of tackifiers that can be used herein include low molecular weight hydrogenated hydrocarbon resin, partially hydrogenated water-white hydrocarbon resin, water white cycloaliphatic hydrocarbon resin, aromatic modified cycloaliphatic hydrocarbon resin, and combinations thereof.

In one embodiment, the composition disclosed herein includes a plasticizer. Non-limiting examples of plasticizers that can be used herein include hydrogenated cycloaliphatic hydrocarbon resin, a trimellitate, an ester, epoxidized vegetable oil, high molecular weight ortho-phthalates, naphthenic hydrocarbon plasticizer, and silicone oil.

In one embodiment, the additive may include one or more acid scavenger. Non-limiting examples of acid scavengers that can be used herein broadly include stearates, carbonates, hydroxides and hydrotalcites. For example, acid scavengers include calcium stearate, calcium zinc stearate or epoxidized octyl stearate, zinc carbonates, magnesium and aluminum hydroxide carbonate, magnesium hydroxide, and synthetic hydrotalcites including magnesium/aluminum-hydrotalcite.

In one embodiment, the composition includes a UV dye. A non-limiting example of the UV dyes that can used be are 2,2′-(2,5-thiophenediyl)bis(5-tert-butylbenzoxazole), 2,2′-(1,2-ethenediyl)bis(4,1-phenylene)bisbenzoxazole, Solvent yellow 43, carbon black, Pigment Yellow 101, N,N′-Bis(2,6-diisopropylphenyl)-3,4,9,10-perylenetetracarboxylic Diimide, other perylene dyes and anthracene dyes.

The compositions disclosed herein provide a variety of benefits over existing, traditional compositions. Non-limiting examples of such benefits include:
Increasing the inertness and durability of materials that are more environmentally friendly.
Engineering a coating formulation to be responsive to the substrate where one of the additives migrates from the bulk of the coating to the problematic substrate to augment the interface between the coating and substrate.
Engineering a coating formulation to be responsive to the environment where one of the additives migrates to the coating/air interface to augment its properties.
Engineering a coating formulation to be responsive to a stimulus like heat or magnetism using which one of the additives is manipulated to initiate a reaction or migrate within the coating (e.g., to the interface).
Engineering a coating formulation to be responsive to uptake of foreign components where the additive responds to, targets, or deactivates any external material from the harsh environment like moisture, noxious gases such as sulfur oxides, or unwanted particles, such as metal particles/shavings.
Engineering coating to have discrete rheological properties across the cross-section.

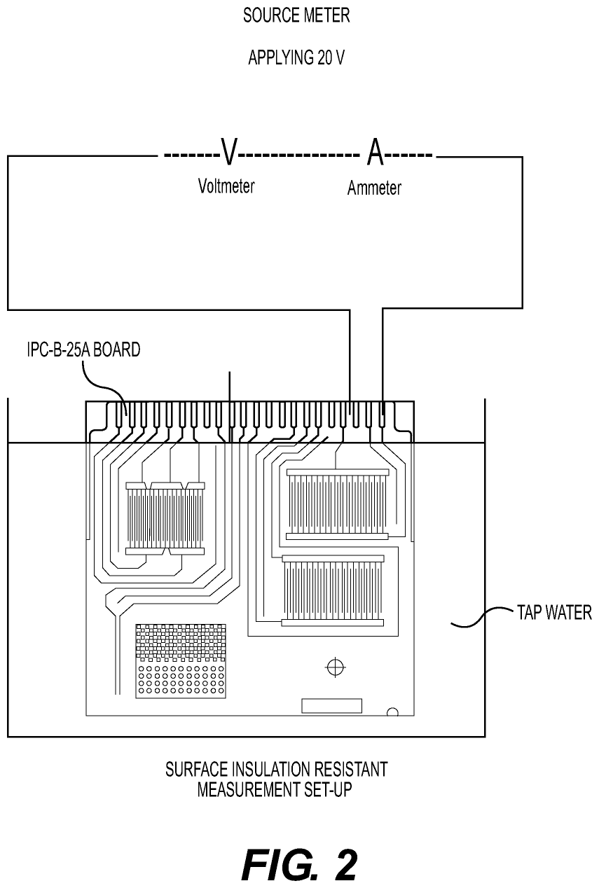

The foregoing benefits can be used to protect an electronic device from conductive materials from the external environment, such as water or bodily fluids, dust or other particulates, and the like. Graphical representations of the compositions used to make the novel gel-state coatings, methods of treating substrates with the gel-state coating and substrates comprising the gel-state coatings are provided in FIGS. 2-7.

Referring to FIG. 2, the schematic shown herein exemplifies a set-up used to measure insulation resistance on the printed circuit boards described herein. In particular, FIG. 2 shows how the insulation properties were measured on various circuits on a coated industry standard IPC-B-25A board when immersed in tap water for 30 minutes at 20 V.

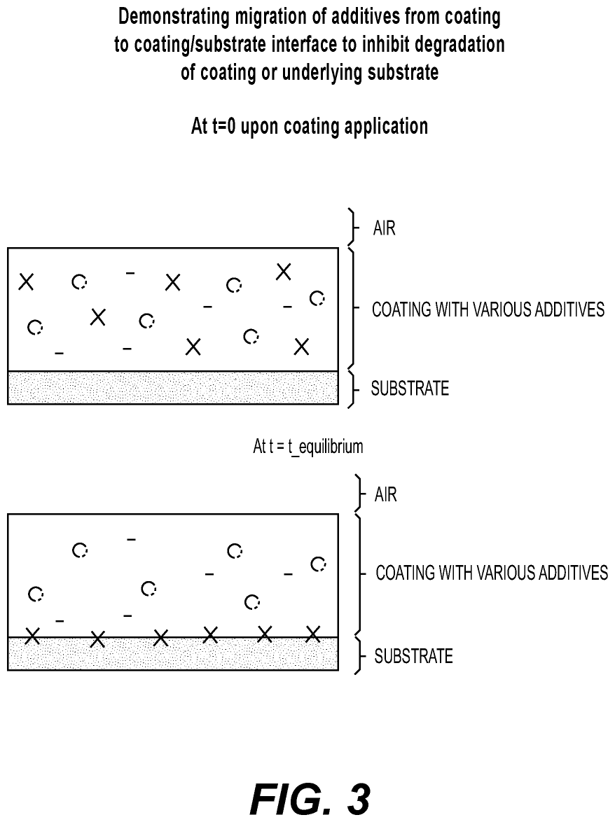

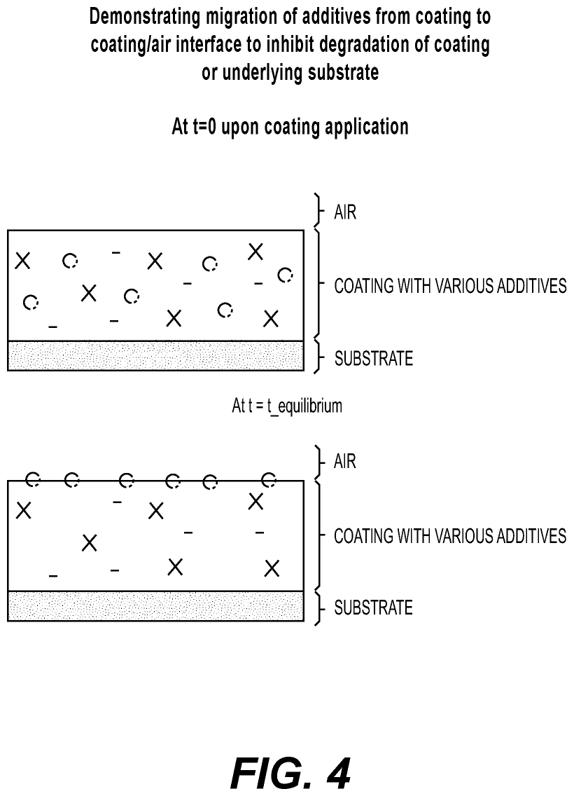

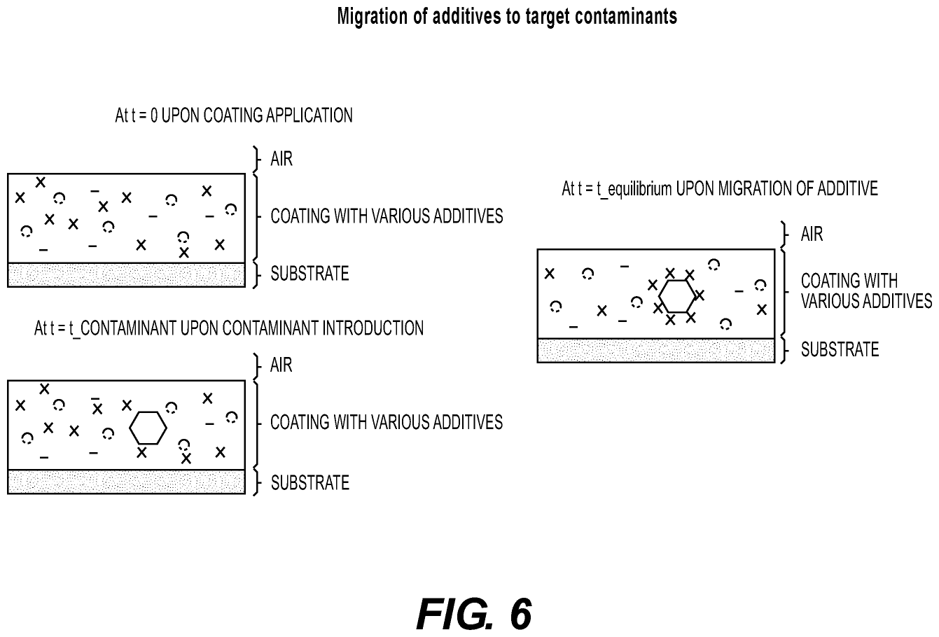

The mechanisms by which the additives disclosed herein lead to improved properties are exemplified in FIGS. 5 and 6, which demonstrate migration of additive from the coating to an interface either at the substrate surface (FIG. 3) or at the air surface (FIG. 4). For example, FIG. 3 shows migration of additive(s) from the coating to the coating/substrate interface. This embodiment can be used to apply a passivating layer on the substrate. FIG. 4 shows a second schematic demonstrating migration of additive from coating to coating/air interface. This embodiment can be used to add mechanical properties to the coating itself.

The mechanisms described above can be specifically selected by changing the way in which the composition comprising the various additives is applied to the substrate. For example, as shown in FIG. 5, a stepwise application of various additives demonstrates coating the substrate by first applying a passivator (in step 1) prior to applying a composition with one or more additional additives (in step 2). Finally, step 3 of FIG. 5 shows the application of insulating (e.g., resisting molecular diffusion, increasing electrical resistance, etc.) layer on top of the composition.

Once the desired coating is applied to the substrate via any method described herein, including the stepwise method of FIG. 5, a gel coating is formed.

In certain embodiments, the coatings described herein can be formulated to allow additives to migrate out of the coating depending on a desired action. For example, FIG. 6 shows a schematic demonstrating the migration of additives to specific materials from external environment that could impact coating performance, such as rust or metal particulates. In addition to metal particulates, materials from the environment that can impact coating performance can include moisture, dust, solder flux residue, any fluids the coating may see once it is assembled into the device like antifreeze, windshield wiper fluid, brake oil, etc.

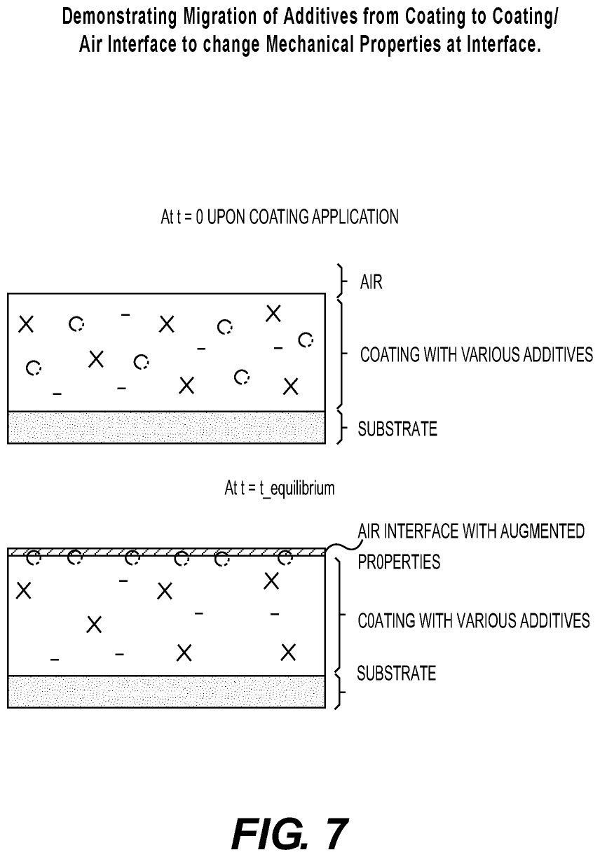

In another embodiment, the coatings described herein can be formulated to allow additives to migrate to the surface of the coating to provide an insulating layer on top of the coating. For example, FIG. 7 shows a sixth schematic demonstrating migration of an additive from coating to coating/air interface to augment the properties at the air-coating interface.

The various mechanisms allow one to modify the additives to achieve desired characteristics that allow the disclosed durable coatings to be used in a variety of applications, such as automotive electronic coatings that can withstand high temperatures and harsh environments that would otherwise cause hydrolytic, thermal, or oxidative decomposition. In general, the present disclosure provides gel-state coatings that exhibit improved durability properties, thereby providing uses not previously possible with gel-state coatings.

In some embodiments, the coating may have electrical insulating properties. As used herein, a coating having electrical insulating properties is defined as a coating that has no or very little electric current flowing through it under the influence of an electric field. In general, an electrical insulator is a material that has little to no electrical conductivity, thus allowing little to no electrical current to flow through it.

In various embodiments, a portion of the internal components, or the entirety of the internal components of the electronic device may be coated with a gel-state coating before additional components are introduced into the device, without the need to mask any parts of the electronic device. Components can be introduced after the coating has been applied and coating will not inhibit the flow of electric current between the component and the electronic device. Manufacturing costs and difficulty are generally increased due to masking. Using a gel-state coating as disclosed herein can result in a decrease in both manufacturing costs and difficulty, due to the need for masking having been greatly reduced or eliminated altogether.

The viscoplastic properties of the film formers described herein allow for the gel-state coating to flow in certain situations. This allows for easy rework of coated printed circuit board assemblies. With traditional conformal and vacuum coatings that do not exhibit flow or deformation, rework of coating to solder or repair existing components is difficult.

In some embodiments, the solvated coating may spread on a substrate as described by the spreading coefficient (S), which is shown in the following equation:

S=γ_{SA}−(γ_{SC}+γ_{CA})

In the above-mentioned equation, γ_{SA} represents the surface energy between the substrate and the air, γ_{SC} represents the surface energy between the substrate and the coating, and γ_{CA} represents the surface energy between the coating and the air. Spreading may occur when the spreading coefficient is positive, or γ_{SA} is greater than (γ_{SC}+γ_{CA}). When the spreading coefficient is positive, this means that wetting of the coating on the substrate will be complete. On the other hand, when the spreading coefficient is not positive, only partial or incomplete wetting is achieved. Instead, the spreading liquid may form globules or floating lens.

In one embodiment, when applied as a coating the dried or unsolvated gel-state coating may range in thickness from 1 μm to 500 μm, such as 5 μm to 100 μm, such as 10 μm to 50 μm. Coating thickness may be measured by non-destructive optical techniques, such as ellipsometry, spectral reflectance techniques, such as interferometry, and confocal microscopy. Non-limiting examples of destructive methods to measure coating thickness includes SEM. Traditional coatings, such as conformal and vacuum coatings, are typically much thicker. For example, traditional coatings typically range in thickness from up to hundreds of microns, which may impede both the radio frequency and Wi-Fi transmission of the electronic device, and further acts as a thermal insulator. The thinner range of a gel-state coating does not adversely affect the functionality of an electronic device, nor does it act as a thermal insulator. A non-limiting example of a functioning electronic device is a fully assembled printed circuit board. A fully assembled printed circuit board with a gel-state coating will exhibit normal radio frequency performance, normal thermal properties, and other normal functionalities.

In an embodiment, the at least one film former may include a hydrophobic material, such as a material comprising polyolefins, polyacrylates, polyurethanes, epoxies, polyamides, polyimides, polysiloxanes.

In an embodiment, the disclosed composition may further comprise additives that improve the manufacturing of the composition, such as surfactants, dispersants, and the like. The composition may also include additives that modify and improve the rheological properties of a chemical formulation. Examples of surfactants may include ionic and non-ionic industrial surfactants such as Triton-X, Capstone, and the like, and molecules such as fatty acid alcohols, esters, acids, or amides that show surface active properties. Examples of dispersants and rheological modifiers may include electrostatically stabilizing molecules such as long chain polyacrylic acid, sterically stabilizing highly branched polymer molecules, bulk viscosity increasing nanoparticles, or sub-micron sized particles of metal oxides. Other materials that exhibit elastoviscoplastic properties may be used as a gel-state coating.

In some embodiments, the composition described herein may also be suspended or dissolved in an appropriate carrier solvent. Non-limiting examples of appropriate carrier solvents may be low molecular weight mineral oils, paraffins or iso-paraffins, alkanes or iso-alkanes, low molecular weight linear silicones or cyclic silicones, alkyl acetates, ketones, fully or partially halogenated hydrocarbons (including, but not limited to, alkanes, alkenes, alkynes, aromatic compounds, and the like), or aldehydes. In one embodiment, the carrier solvent comprises methylcyclohexane.

A gel-state coating described herein can be designed to protect against different types of liquids. A gel-state coating may exhibit hydrophobic, hydrophilic, oleophobic, or oleophilic characteristics, or any combination thereof. In one embodiment, the gel-state coating contains a hydrophobic material such as a polysiloxane.

In some embodiments, the gel-state coating may have aesthetic alterations made. The refractive index of the coating can be engineered using techniques known in the art. In one embodiment the gel-state coating can be engineered to match the refractive index of transparent materials. Matching the refractive index of transparent materials may maintain the clarity and transparency of the final product. In other embodiments, the refractive index of the gel-state coating may be engineered to match the refractive index of other desired materials.

In one embodiment, there is described a method of protecting an electronic device from liquid contamination. In this embodiment, protection of an electronic device can be achieved by treating the electronic device with a gel-state coating, as disclosed above.

A number of different methods can be used to form the described coating. Non-limiting examples of methods that can be used to form the disclosed coatings include physical processes, such as printing, spraying, dipping, rolling, brushing, jetting, blade coating, or needle dispensing. Other techniques may also be used to form a moisture-resistant coating.

As previously disclosed, the properties of a gel-state coating allow for the treating of an electronic device without the need to mask components prior to treating. Thus, the disclosed method encompasses treating an electronic device with masked or unmasked components. Components may be introduced subsequent to the coating without the electric current between the electronic device and the component being impeded.

In one embodiment, a portion or the entirety of an internal component of an electronic device may be coated with a gel-state coating in a single application. In another embodiment, the gel-state coating may be applied as a coating to only certain parts of the electronic device. Still, in another embodiment, gel coating may be applied to the electronic device in multiple applications.

Traditional conformal coatings and vacuum coatings have limited methods of application. Due to the need for masking many components on electronic devices, certain methods of coating are not available. A larger variety of application methods may be used to apply the described coatings. Certain application methods may allow for a thinner gel-state coating to be applied to the electronic device. Non-limiting examples of how gel-state coatings can be applied to an electronic device include atomized or non-atomized spraying, dip coating, film coating, jetting, or needle dispensing. Gel-state coatings can also be applied using other methods, for example through vapor depositing. Non-limiting examples of these vapor deposition techniques include chemical vapor deposition (CVD), plasma-based coating processes, atomic layer deposition (ALD), physical vapor deposition (PVD), vacuum deposition processes, sputtering, etc.

In one embodiment, the use of any of the disclosed methods of application of a gel-state coating to an electronic device will result in a gel-state coating on the electronic device with a thickness in the range of 1 to 100 μm. The coating thickness may not inhibit the functionality or the thermal properties of the electronic device. Furthermore, the viscous properties of the gel-state coating may allow for the coating to be deformed or flow when a component is introduced.

As indicated above, non-limiting example of an electronic device a gel-state coating may be applied to is a printed circuit board. The use of traditional conformal coating and vacuum coating for printed circuit boards is expensive due to the need to mask many components and the limited number of application methods that can be used. For instance, dip coating is difficult to use as a conformal coating application because the coating penetrates everywhere and masking must therefore be perfect. In this example, the printed circuit board can be coated with the gel-state coating using the dip coating method, as there is no need for masking. Any connectors, such as connecting male connectors to base female connectors on the printed circuit board, can be connected after coating without the electric current being affected. The gel-state coating flows under an applied force or deforms to allow the connection to be made.

### Exemplary Deposition Methods

In one embodiment, the disclosed composition may be dispensed using a syringe and needle. For example, a syringe can be fitted with a needle, with a gauge having a gauge size ranging from 10 to 32, such as a needle having a gauge size of 16, 18 or 20, which will vary depending on the application required.

In another embodiment, the disclosed composition may be dispensed using a manual spraying device. For example, a hand-held spray gun can be used to atomize a coating, such as by using compressed air or nitrogen.

In another embodiment, the disclosed composition may be dispensed using an automated dispensing mechanism that may be used to apply a coating to an electronic device. For example, various nozzles that may be used to dispense a coating as described herein, such as a Nordson Asymtek™ wide beam spray valve. In other embodiments, the nozzle may comprise a spray valve comprises a PVA film coat valve, or a valve used in a PVA delta 6 automated coating dispensing machine.

### Measurement Techniques

Following the application of a coating to an electronic device, the various properties may be measured in the following manners.

The hydrophobicity or hydrophilicity of a coating may be measured by observing the contact angle a water droplet makes on the surface of the coating. The oleophobicity or oleophilicity of a coating may be measured by observing the contact angle a droplet of hexadecane makes on the surface of the coating.

The electrical insulation of a coating may also be determined by measuring the dielectric withstanding voltage on a coated circuit board. A continuously increasing voltage may be applied on the coated circuit board, and the voltage at which the current arcs through to air may be determined. This voltage is a measure of the effectiveness of the coating.

The electrical insulation of a coating may also be determined by measuring a material electrical property of the coating, such as the loss tangent or the dielectric constant using a network analyzer.

The non-Newtonian, viscoelastic, viscoplastic, and elastoviscoplastic nature of the coating may be measured by looking at various properties. The response of the coating to an applied stress or strain may be measured using a rheometer to study the deformation of the coating. The viscoelastic moduli may be measured using a Small Angle Oscillatory Stress sweep, and the yield stress and high shear viscosity may be measured using a stress sweep. Degree of deformation can also be measured by quantifying hardness, modulus, tack, failure strain, creep, and ductility in tensile, compressive, and shear directions.

The features and advantages of the present invention are more fully shown by the following examples which are provided for purposes of illustration and are not to be construed as limiting the invention in any way.

### EXAMPLES

The following examples disclose methods of preparing gel state coatings according to the present disclosure. non-Newtonian, viscoelastic, viscoplastic, and/or elastoviscoplastic compositions for application as a coating to an electronic device. Following the preparation, the composition may be applied to an electronic device using known techniques to form a protective coating.

### Example 1

The following example provides a method for preparing a silicone-free gel-state coating that has improved performance properties according to the present disclosure.

A composition comprising the following ingredients was made: electrical insulator/film former/rheology modifiers comprising 8.99% by weight styrenic block copolymer and 8.99% by weight of polyalphaolefin; a passivator comprising 0.18% by weight of dodecanedioic acid, 1,12-bis[2-(2-hydroxybenzoyl)hydrazide]; a primary antioxidant comprising 0.05% by weight of benzenepropanoic acid, 3,5-bis (1,1-dimethylethyl)-4-hydroxy-, octadecyl ester; a secondary antioxidant comprising 0.09% by weight of propanoic acid, 3,3′-thiobis-, 1,1′-ditridecyl ester; and a UV dye comprising 0.02% by weight of 2,2′-(2,5-thiophenediyl) bis(5-tert-butylbenzoxazole).

These ingredients were added to a glass beaker and mixed in a carrier solvent comprising 81.74% by weight of methyl cyclohexane. Mixing occurred using a magnetic stirrer at room temperature for 8 hours.

### Example 2

A composition substantially similar to Example 1, but without the UV dye was made. It was comprised of the following ingredients: electrical insulator/film former/rheology modifiers comprising 8.99% by weight styrenic block copolymer and 8.99% by weight of polyalphaolefin; a passivator comprising 0.18% by weight of dodecanedioic acid, 1,12-bis[2-(2-hydroxybenzoyl)hydrazide]; a primary antioxidant comprising 0.05% by weight of benzenepropanoic acid, 3,5-bis (1,1-dimethylethyl)-4-hydroxy-, octadecyl ester; and a secondary antioxidant comprising 0.09% by weight of propanoic acid, 3,3′-thiobis-, 1,1′-ditridecyl ester.

These ingredients were added to a glass beaker and mixed in a carrier solvent comprising 81.74% by weight of methyl cyclohexane. Mixing occurred using a magnetic stirrer at room temperature for 8 hours.

### Comparative Example 1

This comparative composition was similar to Examples 1 and 2, but without additives including passivators, anti-oxidants and dyes. It was comprised of the following ingredients: electrical insulator/film former/rheology modifiers comprising 8.99% by weight styrenic block copolymer and 8.99% by weight of polyalphaolefin mixed in a carrier solvent comprising 82% by weight of methyl cyclohexane.

All ingredients were added to a glass beaker and stirred using a magnetic stirrer at room temperature for 8 hours.

### Example 3

This example was based on a formulation with styrene-[ethylene-(ethylene-propylene)]-styrene (SEEPS) block copolymer with additives. The composition comprised 4% by weight of SEEPS polymer, white mineral oil (8%), a passivator comprising 0.08% by weight of benzenepropanoic acid, 3,5-bis(1,1-dimethylethyl)-4-hydroxy-, 2-[3-[3,5-bis(1,1-dimethylethyl)-4-hydroxyphenyl]-1-oxopropyl]hydrazide, 0.08% by weight of a primary phenolic antioxidant comprising a reaction mass of isomers of: C7-9-alkyl 3-(3,5-di-tert-butyl-4-hydroxyphenyl) propionate, and 0.12% by weight of a thioether antioxidant comprising propanoic acid, 3,3′-thiobis-, 1,1′-ditridecyl ester, mixed in a carrier solvent comprising 87.7% by weight of methyl cyclohexane.

All ingredients were added to a glass beaker and stirred using a magnetic stirrer at room temperature for 8 hours.

### Comparative Example 2

This comparative composition was similar to Example 3, but without additives including passivators, antioxidants and dyes. It was comprised of the following ingredients: 4% by weight of styrene-[ethylene-(ethylene-propylene)]-styrene (SEEPS) and 8% by weight of white mineral oil mixed in a carrier solvent comprising 88% by weight of methyl cyclohexane.

All ingredients were added to a glass beaker and stirred using a magnetic stirrer at room temperature for 8 hours.

### Example 4

This example was based on a formulation with styrene-[ethylene-(ethylene-propylene)]-styrene (SEEPS) block copolymer with endblock stabilizer and other additives.

The composition comprised 4% by weight styrenic block copolymer and 7% by weight of polyalphaolefin; 1.1% by weight of a hydrocarbon resin endblock stabilizer sold by Eastman called Endex 155®, 0.11% by weight of the passivator benzamide, 2-hydroxy-N-1H-1,2,4-triazol-3-yl-, 0.11% by weight of the phenolic antioxidant benzenepropanoic acid, 3,5-bis(1,1-dimethylethyl)-4-hydroxy-, octadecyl ester, 0.06% by weight of the thioether antioxidant propanoic acid, 3,3′-thiobis-, 1,1′-ditridecyl ester, mixed in a carrier solvent comprising 87.62% by weight of methyl cyclohexane.

The hydrocarbon resin endblock stabilizer was added to methylcyclohexane in a beaker and stirred at 80° C. until dissolution. All other ingredients were further added and stirred at room temperature for 8 hours.

### Comparative Example 3

This comparative composition was similar to Example 4, but without additives including passivators, antioxidants and dyes. It was comprised of the following ingredients: The composition comprised 4% by weight styrenic block copolymer and 7% by weight of polyalphaolefin mixed in 89% by weight of methylcyclohexane.

All ingredients were added to a glass beaker and stirred using a magnetic stirrer at room temperature for 8 hours.

### Example 5

This example was based on a formulation with 3.55% by weight of styrene-ethylene/butylene-styrene (SEBS); 0.89% by weight styrene-ethylene/propylene-styrene (SEPS) block copolymer; 3.55% by weight of polyalphaolefin; passivator comprising 0.18% by weight of dodecanedioic acid, 1,12-bis[2-(2-hydroxybenzoyl)hydrazide]; a phenolic antioxidant comprising 0.045% by weight benzenepropanoic acid, 3,5-bis(1,1-dimethylethyl)-4-hydroxy-, octadecyl ester (0.045%); a thioether antioxidant comprising 0.09% propanoic acid, 3,3′-thiobis-, 1,1′-ditridecyl ester, mixed in 81.74% by weight of methylcyclohexane.

All ingredients were added to a glass beaker and stirred using a magnetic stirrer at room temperature for 8 hours.

### Example 6

This example was based on a formulation with 3.55% by weight of styrene-ethylene/butylene-styrene (SEBS); 0.53% by weight styrene-ethylene/propylene-styrene (SEPS); and maleic anhydride treated SEBS block copolymers—SEBS (3.55%), SEPS (0.53%), maleic anhydride treated SEBS (0.36%); 3.55% by weight of polyalphaolefin; passivator comprising 0.08% by weight of dodecanedioic acid, 1,12-bis[2-(2-hydroxybenzoyl)hydrazide]; a phenolic antioxidant comprising 0.02% by weight benzenepropanoic acid, 3,5-bis(1,1-dimethylethyl)-4-hydroxy-, octadecyl ester (0.045%); a thioether antioxidant comprising 0.04% propanoic acid, 3,3′-thiobis-, 1,1′-ditridecyl ester, mixed in a solvent comprising 81.74% by weight of methylcyclohexane.

All ingredients were added to a glass beaker and stirred using a magnetic stirrer at room temperature for 8 hours.

### Example 7

This example was based on a formulation with polyisobutylene and SEEPS copolymer. In particular, 10% by weight of polyisobutylene (10%), 10% by weight of SEEPS polymer; 0.1% by weight of a passivator comprising benzamide, 2-hydroxy-N-1H-1,2,4-triazol-3-yl-, 0.2% by weight of a phenolic antioxidant comprising a reaction mass of isomers of: C7-9-alkyl 3-(3,5-di-tert-butyl-4-hydroxyphenyl) propionate; 0.1% by weight of a thioether antioxidant comprising propanoic acid, 3,3′-thiobis-, 1,1′-ditridecyl ester, mixed in a solvent comprising 79.60% by weight of isoparaffin.

All ingredients were added to a glass beaker and stirred using a magnetic stirrer at room temperature for 8 hours.

### Example 8

This example was based on a formulation with polyethylene/polypropylene (PE/PP) copolymer and silicone oil. The composition comprised 3% by weight of a PE/PP copolymer; 10% by weight of a methyl terminated PDMS (30,000 cSt), 0.13% by weight of a passivator comprising dodecanedioic acid, 1,12-bis[2-(2-hydroxybenzoyl)hydrazide]; 0.04% by weight of a phenolic antioxidant comprising benzenepropanoic acid, 3,5-bis(1,1-dimethylethyl)-4-hydroxy-, octadecyl ester; and 0.04% by weight of propanoic acid, 3,3′-thiobis-, 1,1′-ditridecyl ester, mixed in a solvent comprising 86.80% by weight of methylcyclohexane.

All ingredients were added to a glass beaker and stirred using a magnetic stirrer at room temperature for 8 hours.

### Example 9

This example was based on a formulation with lithium stearate and alumina. In particular, the composition comprised 2.8% by weight lithium stearate, 1.1% by weight organosilane treated hydrophobic alumina; 9.4% by weight polyalphaolefin; a passivator comprising 0.13% of dodecanedioic acid, 1,12-bis[2-(2-hydroxybenzoyl) hydrazide], a phenolic antioxidant comprising 0.03% benzenepropanoic acid, 3,5-bis(1,1-dimethylethyl)-4-hydroxy-, octadecyl ester), a thioether antioxidant comprising 0.07% propanoic acid, 3,3′-thiobis-, 1,1′-ditridecyl ester; UV dye comprising 0.01% by weight of 2,2′-(2,5-thiophenediyl)bis(5-tert-butylbenzoxazole), azeotropic fluoroether solvent mixture (86.49%).

The lithium stearate, polyalphaolefin, and azeotropic fluoroether solvent mixture were added into a beaker and stirred at 60° C. until lithium stearate completely dissolved.

The mixture is cooled to room temperature and organosilane treated hydrophobic alumina is added and mixed using a high shear homogenizer. The rest of the ingredients are added and mixed until dissolved.

### Example 10

The following example provides a method for preparing a polyacrylate coating that has improved performance properties according to the present disclosure.

A 20 mL scintillation vial with septa cap was charged with stir bar, 0.500 g butyl acrylate, 2.500 g methyl methacrylate, 0.060 g azobisisobutyronitrile, and 1.500 g n-butyl acetate. After sealing the vial, the solution was gently purged with nitrogen using hypodermic needles through the septa cap while stirring for 30 minutes. After purging, inlet and outlet needles were removed, and the vial was transferred to an aluminum heating block and heated at 85° C. with stirring for 5 hours. To quench the reaction, the vial was removed from the heating block, opened to air, and cooled with an ice bath.

### Example 11

The following example provides a method for preparing a polyacrylate coating that has improved performance properties according to the present disclosure.

A 20 mL scintillation vial with septa cap was charged with stir bar, 2.000 g 2-ethylhexyl acrylate, 1.700 g isobornyl methacrylate, 0.074 g azobisisobutyronitrile, and 0.200 g n-butyl acetate. After sealing the vial, the solution was gently purged with nitrogen using hypodermic needles through the septa cap while stirring for 30 minutes. After purging, inlet and outlet needles were removed, and the vial was transferred to an aluminum heating block and heated at 85° C. with stirring for 5 hours. To quench the reaction, the vial was removed from the heating block, opened to air, and cooled with an ice bath.

The reaction mixture was diluted to 10.7 wt % using n-butyl acetate, which was mixed using magnetic stirrer at room temperature for 30 minutes.

### INDUSTRIAL APPLICABILITY

The disclosed composition for forming a conformal gel coating, the conformal coating for a device or substrate, and a method of coating a device or substrate with the conformal coating may be used to protect a device or substrate from various environments by serving as protective layer.

In an embodiment, the surface may comprise a metal and the unwanted environment is corrosive and aqueous, such as condensation, tap water, sweat, sebum, salt water, carbonated beverages, coffee, liquid coolant or antifreeze. In an embodiment, the surface comprises a metal that exhibits galvanic corrosion and the unwanted environment causes galvanic corrosion. More generally, the surface may comprise any metal that could undergo oxidation and the unwanted environment causes oxidation selected from air, oxygen, or water vapor.

In another embodiment, the surface comprises active electronics in a printed circuit board and the unwanted environment comprises corrosive gases selected from chlorine, water vapor, hydrogen sulfide, hydrogen chloride or oxides of nitrogen and sulfur. In yet another embodiment, the surface comprises active electronics in a printed circuit board and the unwanted environment comprises conductive liquids selected from water, sweat, and other corrosive fluids.

A conformal gel coating constructed according to principles of the present disclosure generally exhibits improved functional durability while retaining the deformability as a result of the combination of at least one film former; and at least one additive.

For example, the at least one film former may comprise polyolefins, polyacrylates, polyurethanes, epoxies, polyamides, polyimides, polysiloxanes, or combinations thereof.

The one or more additive may be selected from: antioxidants; passivators; UV absorbers or stabilizers; rheology modifiers; adhesion promoters; wetting agents; tackifiers; plasticizers; dispersing agents; leveling agents; defoamers; processing additives; or combinations thereof.

The antioxidant may comprise a phenolic antioxidant, an amine antioxidant, a thioether antioxidant, a phosphite antioxidant, or combinations thereof.

The phenolic antioxidants may be selected from Benzenepropanoic acid, 3,5-bis(1,1-dimethylethyl)-4-hydroxy-, octadecyl ester (CAS #2082-79-3), Benzenepropanoic acid, 3,5-bis(1,1-dimethylethyl)-4-hydroxy-,2,2-bis[[3-[3,5-bis(1,1-dimethylethyl)-4-hydroxyphenyl]-1-oxopropoxy]methyl]-1,3-propanediyl ester (CAS #6683-19-8), reaction mass of isomers of: C7-9-alkyl 3-(3,5-di-tert-butyl-4-hydroxyphenyl) propionate (CAS #125643-61-0), 1,3,5-Triazine-2,4,6(1H,3H,5H)-trione, 1,3,5-tris {[3,5-bis(1,1-dimethylethyl)-4-hydroxyphenyl] methyl}- (CAS #27676-62-6) or Benzenepropanoic acid, 3-(1,1-dimethylethyl)-4-hydroxy-5-methyl-, 2,4,8,10-tetraoxaspiro [5.5]undecane-3,9-diylbis(2,2-dimethyl-2,1-ethanediyl) ester (CAS #90498-90-1), and combinations thereof.

The amine antioxidants may be selected from Benzenamine, N-phenyl-reaction products with 2,4,4-trimethylpentene (CAS #68411-46-1), 1-Naphthalenamine, N-phenyl-ar-(1,1,3,3-tetramethylbutyl)- (CAS #68259-36-9), 4,4′-Dioctyldiphenylamine (CAS #101-67-7), other alkylated amines, and combinations thereof.

The thioether antioxidants may be selected from propanoic acid, 3-(dodecylthio)-,1,1′-[2,2-bis[[3-(dodecylthio)-1-oxopropoxy]methyl]-1,3-propanediyl]ester (CAS #29598-76-3) or Propanoic acid, 3,3′-thiobis-, 1,1′-ditridecyl ester (CAS #10595-72-9), and combinations thereof.

The phosphite antioxidants may be selected from tris(2,4-di-tert-butylphenyl) phosphite (CAS #31570-04-4), Butylidenebis[2-tert-butyl-5-methyl-p-phenylene]-P,P,P′,P′-tetratridecylbis(phosphine) (CAS #13003-12-8), 12H-Dibenzo[d,g][1,3,2]dioxaphosphocin,2,4,8,10-tetrakis(1,1-dimethylethyl)-6-[(2-ethylhexyl)oxy]- (CAS #126050-54-2) or Tris(2,4-ditert-butylphenyl) phosphite (CAS #31570-04-4), and combinations thereof.

The passivators may comprise a hydrazide or a triazole, selected from dodecanedioic acid, 1,12-bis[2-(2-hydroxybenzoyl)hydrazide] (CAS #63245-38-5), Benzenepropanoic acid, 3,5-bis(1,1-dimethylethyl)-4-hydroxy-, 2-[3-[3,5-bis(1,1-dimethylethyl)-4-hydroxyphenyl]-1-oxopropyl]hydrazide (CAS #32687-78-8), 1,2,4-Triazole (CAS #288-88-0), 2-Hydroxy-N-1H-1,2,4-triazol-3-ylbenzamide (CAS #36411-52-6), 1H-Benzotriazole-1-methanamine, N,N-bis(2-ethylhexyl)-ar-methyl-(CAS #94270-86-7), 1H-1,2,4-Triazole-1-methanamine, N,N-bis(2-ethylhexyl)- (CAS #91273-04-0), and combinations thereof.

The UV absorber or stabilizer may comprise carbon black, rutile titanium oxide, hindered amines, benzophenones, and combinations thereof.

The rheology modifier may comprise sodium polyacrylates, polyamide wax, polyethylene wax, hydrogenated castor oils, attapulgite clay, fumed silica, precipitated silica, metal-oxide particles, and combinations thereof.

The adhesion promoter may comprise chlorinated polyolefins, cyanoacrylate primers, polyester alkyl ammonium salts, aminofunctional polyethers, maleic anhydride, carboxylated polypropylene, glycidylmethacrylate-functionalized polyolefins, trimethoxyvinylsilane, silanes, and combinations thereof.

The wetting or dispersing agent may comprise alkylammonium salts of a polycarboxylic acid, alkylammonium salt of an acidic polymer, salt of unsaturated polyamine amides and acidic polyesters, maleic anhydride functionalized ethylene butyl acrylate copolymer, other ionic or non-ionic surfactants, and combinations thereof.

The tackifier may comprise hydrogenated hydrocarbon resins or cycloaliphatic hydrocarbon resins.

The plasticizer may comprise hydrogenated cycloaliphatic hydrocarbon resins, trimellitates, high molecular weight orthophthalates, silicone oils, octyl epoxy esters or hydrotreated light naphthenic petroleum distillates.

The leveling agents may comprise silicones, liquid polyacrylates, ionic surfactants, non-ionic surfactants or mixtures thereof.

The disclosed composition may be formulated in one or more solvents such as aromatic solvents selected from toluene, xylene and naphtha, alkanes selected from isoparaffin solvents, hexane, methylcyclohexane, alkenes, alcohols selected from butanol, alkyl acetates selected from tert-butyl acetate, alkyl ethers, ketones selected from methyl ethyl ketone, aldehydes, and fully or partially halogenated hydrocarbons.

The composition may also comprise at least one pigment or UV dye selected from 2,2′-(2,5-thiophenediyl)bis(5-tert-butylbenzoxazole) (CAS #7128-64-5), 2,2′-(1,2-ethenediyl)bis(4,1-phenylene)bisbenzoxazole (CAS #1533-45-5), Solvent yellow 43 (CAS #19125-99-6), carbon black (CAS #1333-86-4), Pigment Yellow 101 (CAS #2387-03-3), N,N′-Bis(2,6-diisopropylphenyl)-3,4,9,10-perylenetetracarboxylic Diimide (CAS #82953-57-9), other perylene dyes and anthracene dyes.

The composition may exhibit viscoeleastic, viscoplastic, or elasto-visco-plastic flow properties when formulated in a solvent or once the solvent evaporates upon application. It may also be silicone-free, non-halogenated or both.

The composition may have a volatile organic content of 650 g/L or less.

It may also have a thickness ranging from 25 nm to 500 μm when applied on various surfaces.

In an embodiment, the composition exhibits electrical insulation properties, such that they prevent current leakage or arcing between two metal contacts when the composition is placed between said metal contacts. The electrical insulating properties may also prevent current flowing from active electronics on a printed circuit board to conductive media or environments, or prevent electrostatic discharge from a charge carrier to active electronics on a printed circuit board.

As stated, the additives described herein provide the composition with enhanced durability to oxidative degradation compared to a composition without the additives. For example, the additives may provide the composition with enhanced mechanical stability compared to a composition without the additives, and does not undergo liquefaction, hardening or other phase changes. In an embodiment, one or more of the additives preferentially migrate to the coating/substrate interface to isolate the substrate from the rest of the coating. For example, when the composition is made into a gel coating as described herein, the additive may be a passivator that migrates to and adsorbs onto the coating/substrate interface to inhibit catalytic activity from the substrate. one or more of the additives preferentially migrate to an area of the substrate that is free from the coating to protect the substrate from the environment.

Other embodiments of the invention will be apparent to those skilled in the art from consideration of the specification and practice of the invention disclosed herein. It is intended that the specification and examples be considered as exemplary only, with the true scope of the invention being indicated by the following claims.

1-98. (canceled)

99. A composition for forming a conformal gel coating to protect a substrate, the composition comprising:
at least one film former comprising at least one of polyolefins, polyacrylates, polyurethanes, epoxies, polysiloxanes, or combinations thereof
at least one additive,
wherein said composition is configured to form a conformal gel coating that is deformable, flowable, and electrically insulating.

100. The composition of claim 99, wherein the one or more additive is selected from the group consisting of: antioxidants, passivators, UV absorbers or stabilizers, rheology modifiers, adhesion promoters, wetting agents, tackifiers, plasticizers, dispersing agents, leveling agents, defoamers, processing additives, and combinations thereof.

101. The composition of claim 100, wherein the antioxidants comprise a phenolic antioxidant, an amine antioxidant, a thioether antioxidant, a phosphite antioxidant, or combinations thereof.

102. The composition of claim 101, wherein the phenolic antioxidants comprise one or more compounds selected from the group consisting of: benzenepropanoic acid, 3,5-bis(1,1-dimethylethyl)-4-hydroxy-, octadecyl ester (CAS #2082-79-3), benzenepropanoic acid, 3,5-bis(1,1-dimethylethyl)-4-hydroxy-,2,2-bis[[3-[3,5-bis(1,1-dimethylethyl)-4-hydroxyphenyl]-1-oxopropoxy]methyl]-1,3-propanediyl ester (CAS #6683-19-8), a reaction product of: C7-9-alkyl 3-(3,5-di-tert-butyl-4-hydroxyphenyl) propionate (CAS #125643-61-0), 1,3,5-triazine-2,4,6(1H,3H,5H)-trione, 1,3,5-tris {[3,5-bis(1,1-dimethylethyl)-4-hydroxyphenyl] methyl}- (CAS #27676-62-6) or Benzenepropanoic acid, 3-(1,1-dimethylethyl)-4-hydroxy-5-methyl-, 2,4,8,10-tetraoxaspiro [5.5]undecane-3,9-diylbis(2,2-dimethyl-2,1-ethanediyl) ester (CAS #90498-90-1), and combinations thereof.

103. The composition of claim 101, wherein the amine antioxidants comprise one or more compounds selected from the group consisting of: benzenamine, N-phenyl-, reaction products of 2,4,4-trimethylpentene (CAS #68411-46-1), 1-naphthalenamine, N-phenyl-ar-(1,1,3,3-tetramethylbutyl)- (CAS #68259-36-9), 4,4′-dioctyldiphenylamine (CAS #101-67-7), other alkylated amines, and combinations thereof.

104. The composition of claim 101, wherein the thioether antioxidants comprise one or more compounds selected from the group consisting of: propanoic acid, 3-(dodecylthio)-,1,1′-[2,2-bis[[3-(dodecylthio)-1-oxopropoxy]methyl]-1,3-propanediyl] ester (CAS #29598-76-3), propanoic acid, 3,3′-thiobis-, 1,1′-ditridecyl ester (CAS #10595-72-9), and combinations thereof.

105. The composition of claim 101, wherein the phosphite antioxidants comprise one or more compounds selected from the group consisting of: tris(2,4-di-tert-butylphenyl) phosphite (CAS #31570-04-4), butylidenebis[2-tert-butyl-5-methyl-p-phenylene]-P,P,P′,P′-tetratridecylbis(phosphine) (CAS #13003-12-8), 12H-dibenzo[d,g][1,3,2]dioxaphosphocin,2,4,8,10-tetrakis(1,1-dimethylethyl)-6-[(2-ethylhexyl)oxy]- (CAS #126050-54-2), Tris(2,4-ditert-butylphenyl) phosphite (CAS #31570-04-4), and combinations thereof.

106. The composition of claim 100, wherein the passivators comprise a hydrazide or a triazole selected from the group consisting of: dodecanedioic acid, 1,12-bis[2-(2-hydroxybenzoyl)hydrazide] (CAS #63245-38-5), benzenepropanoic acid, 3,5-bis(1,1-dimethylethyl)-4-hydroxy-, 2-[3-[3,5-bis(1,1-dimethylethyl)-4-hydroxyphenyl]-1-oxopropyl]hydrazide (CAS #32687-78-8), 1,2,4-Triazole (CAS #288-88-0), 2-Hydroxy-N-1H-1,2,4-triazol-3-ylbenzamide (CAS #36411-52-6), 1H-benzotriazole-1-methanamine, N,N-bis(2-ethylhexyl)-ar-methyl- (CAS #94270-86-7), 1H-1,2,4-triazole-1-methanamine, N,N-bis(2-ethylhexyl)- (CAS #91273-04-0), and combinations thereof.

107. The composition of claim 100, wherein the UV absorbers or stabilizers comprise one or more compounds selected from the group consisting of: carbon black, rutile titanium oxide, hindered amines, benzophenones, and combinations thereof.

108. The composition of claim 100, wherein the rheology modifiers comprise one or more compounds selected from the group consisting of: sodium polyacrylates, polyamide wax, polyethylene wax, hydrogenated castor oils, attapulgite clay, fumed silica, precipitated silica, metal-oxide particles, and combinations thereof.

109. The composition of claim 100, wherein the adhesion promoters comprise one or more compounds selected from the group consisting of: chlorinated polyolefins, cyanoacrylate primers, polyester alkyl ammonium salts, aminofunctional polyethers, maleic anhydride, carboxylated polypropylene, glycidylmethacrylate-functionalized polyolefins, trimethoxyvinylsilane, silanes, and combinations thereof.

110. The composition of claim 100, wherein the wetting or dispersing agents comprise one or more compounds selected from the group consisting of: alkylammonium salts of a polycarboxylic acid, alkylammonium salt of an acidic polymer, salt of unsaturated polyamine amides and acidic polyesters, maleic anhydride functionalized ethylene butyl acrylate copolymer, other ionic or non-ionic surfactants, and combinations thereof.

111. The composition of claim 100, wherein the tackifiers comprise at least one of hydrogenated hydrocarbon resins or cycloaliphatic hydrocarbon resins.

112. The composition of claim 100, wherein the plasticizers comprise at least one compound selected from the group consisting of: hydrogenated cycloaliphatic hydrocarbon resins, trimellitates, high molecular weight orthophthalates, silicone oils, octyl epoxy esters, and hydrotreated light naphthenic petroleum distillates.

113. The composition of claim 100, wherein the leveling agents comprise at least one compound selected from the group consisting of: silicones, liquid polyacrylates, ionic surfactants, non-ionic surfactants, and combinations thereof.

114. The composition of claim 99, further comprising at least one pigment or UV dye selected from the group consisting of: 2,2′-(2,5-thiophenediyl)bis(5-tert-butylbenzoxazole) (CAS #7128-64-5), 2,2′-(1,2-ethenediyl)bis(4,1-phenylene)bisbenzoxazole (CAS #1533-45-5), solvent yellow 43 (CAS #19125-99-6), carbon black (CAS #1333-86-4), pigment yellow 101 (CAS #2387-03-3), N,N′-bis(2,6-diisopropylphenyl)-3,4,9,10-perylenetetracarboxylic Diimide (CAS #82953-57-9), other perylene dyes and anthracene dyes.

115. The composition of claim 99, wherein the conformal gel exhibits viscoelastic, viscoplastic, or elasto-visco-plastic flow properties.

116. The composition of claim 99, wherein the composition is silicone-free.

117. The composition of claim 99, wherein the composition is non-halogenated.

118. The composition of claim 99, comprising a volatile organic content of 650 g/L or less.

119. The composition of claim 99, wherein the conformal gel has a thickness ranging from 25 nm to 500 μm on the substrate.

120. The composition of claim 99, wherein the conformal gel coating acts as a protective interface between the surface and an environment.

121. The composition of claim 120, wherein the surface comprises a metal, and the environment is a corrosive or conductive environment selected from environments with high humidity, condensation, tap water, sweat, sebum, salt water, carbonated beverages, coffee, liquid coolant, or antifreeze.

122. The composition of claim 121, wherein the surface comprises a metal that exhibits galvanic corrosion and the environment causes galvanic corrosion, or wherein the environment is an oxidizing environment containing at least one gas selected from air, oxygen, and water vapor.

123. The composition of claim 121, wherein the surface comprises electronics in a printed circuit board and the unwanted environment comprises at least one corrosive gas selected from the group consisting of: chlorine, water vapor, hydrogen sulfide, hydrogen chloride or oxides of nitrogen and sulfur, or at least one conductive liquid selected from the group consisting of: water, sweat, and other corrosive fluids.

124. The composition of claim 99, wherein the composition exhibits electrical insulation properties that mitigate at least one of:
current leakage or arcing between two metal contacts when said composition is placed between said metal contacts,
current flowing from active electronics on a printed circuit board to conductive media or environments; and
electrostatic discharge from a charge carrier to active electronics on a printed circuit board.

125. The composition of claim 99, wherein said additives provides the composition with at least one property selected from:
enhanced durability to oxidative degradation compared to a composition without said additives; and
enhanced mechanical stability compared to a composition without said additives, and wherein the composition does not undergo liquefaction, hardening or other phase changes.

126. The composition of claim 99, wherein one or more of the additives is found at an interface between the coating and the substrate or is found at an area of the substrate that is free from the coating after application to a substrate.

127. The composition of claim 99, wherein the additive is a passivator that is found at and adsorbs onto an interface between the coating and the substrate to inhibit catalytic activity from the substrate.

128. The composition of claim 99, further comprising at least one solvent.

129. A conformal gel coating to protect an electronic element, the coating comprising:
at least one film former which comprises at least one of polyolefins, polyacrylates, polyurethanes, epoxies, polysiloxanes or combinations thereof;
at least one additive,
wherein said gel coating is deformable, flowable and electrically insulating.

130. The conformal gel coating of claim 129, further comprising at least one solvent.

131. A method of treating an electronic device with a conformal gel coating, the method comprising:
applying the conformal gel coating to the electronic device, wherein the conformal gel coating comprises:
at least one film former which comprises at least one of polyolefins, polyacrylates, polyurethanes, epoxies, polysiloxanes or combinations thereof
at least one additive,
wherein said gel conformal coating is deformable, flowable and electrically insulating.

132. The method of claim 131, wherein the conformal gel coating further comprises at least one solvent.

133. A substrate having a conformal gel coating thereon, the conformal gel coating comprising:
at least one film former comprising at least one of polyolefins, polyacrylates, polyurethanes, epoxies, polysiloxanes or combinations thereof; and
at least one additive,
wherein the conformal gel coating is deformable, flowable, and electrically insulating.
